(19) United States
(12) Patent Application Publication
(10) Pub. No.: US 2002/0127875 A1
(43) Pub. Date: Sep. 12, 2002

(54) Point of use mixing and aging system for chemicals used in a film forming apparatus

(75) Inventors: Timothy Weidman, Sunnyvale, CA (US); Eric (Bram) Britcher, Rancho Cucamonga, CA (US); Todd Balisky, Corona, CA (US)

Correspondence Address: Patent Counsel, M/S 2061, APPLIED MATERIALS, INC., Legal Affairs Department, P.O. Box 450A, Santa Clara, CA, 95052, US

(73) Assignee: Applied Materials, Inc., Santa Clara, CA (US)

(21) Appl. No.: 10/092,980

(22) Filed: Mar. 6, 2002

Related U.S. Application Data
(63) Continuation-in-part of application No. 09/692,660, filed on Oct. 18, 2000.
(60) Provisional application No. 60/160,050, filed on Oct. 18, 1999.

(51) Int. Cl. H01L 21/31; H01L 21/469; B05C 3/00; B05C 19/02

(52) U.S. Cl. 438/778; 438/780; 438/790; 118/429

(57) ABSTRACT

A method for forming a low k dielectric constant material over a substrate. According to one embodiment, the method includes combining, in a mixing apparatus fluidly coupled to a solution applicator, an organo silicate glass (OSG) precursor, a solvent and a surfactant with water and an acid catalyst to form a coating solution; aging the coating solution in the mixing apparatus to form an aged coating solution; transporting the aged coating solution to the solution applicator; and then applying the aged coating solution to the substrate with the applicator.

### CROSS-REFERENCES TO RELATED APPLICATIONS

This application is a continuation-in-part of U.S. application Ser. No. 09/692,660, filed Oct. 18, 2000, entitled ULTRASONIC SPRAY COATING OF LIQUID PRECURSOR FOR LOW K DIELECTRIC COATINGS, having Timothy Weidman, Yunfeng Lu, Michael P. Nault, Michael Barnes and Farhad Moghadam listed as coinventors; which claims the benefit of U.S. Provisional Application Serial No. 60/160,050, filed Oct. 18, 1999. The disclosures of 09/692,660 and 60/160,050 are herein incorporated by reference in their entirety.

### BACKGROUND OF THE INVENTION

Certain embodiments of the present invention relate to methods for forming dielectric layers. More specifically, embodiments of the invention pertain to methods for forming extremely low dielectric constant films that are particularly useful in the manufacture of integrated circuits. Other embodiments of the present invention pertain to an apparatus for mixing various liquid sources used for deposition of the dielectric film to create a mixed solution, aging the mixed solution and then delivering the aged solution to a dielectric film deposition apparatus for the deposition process.

As semiconductor device sizes have become smaller and integration density increases, many issues have become of increasing concern to semiconductor manufacturers. One such issue is that of interlevel “crosstalk.” Crosstalk is the undesired coupling of an electrical signal on one metal layer onto another metal layer, and arises when two or more layers of metal with intervening insulating or dielectric layers are formed on a substrate. Crosstalk can be reduced by moving the metal layers further apart, minimizing the areas of overlapping metal between metal layers, reducing the dielectric constant of the material between metal layers and combinations of these and other methods. Undesired coupling of electrical signals can also occur between adjacent conductive traces, or lines, within a conductive layer. As device geometries shrink, the conductive lines become closer together and it becomes more important to isolate them from each other.

Another such issue is the “RC time constant” of a particular trace. Each conductive trace has a resistance, R, that is a product of its cross section and bulk resistivity, among other factors, and a capacitance, C, that is a product of the surface area of the trace and the dielectric constant of the material or the space surrounding the trace, among other factors. If a voltage is applied to one end of the conductive trace, charge does not immediately build up on the trace because of the RC time constant. Similarly, if a voltage is removed from a trace, the trace does not immediately drain to zero. Thus high RC time constants can slow down the operation of a circuit. Unfortunately, shrinking circuit geometries produce narrower traces, which results in higher resistivity. Therefore it is important to reduce the capacitance of the trace, such as by reducing the dielectric constant of the surrounding material between traces, to maintain or reduce the RC time constant.

Hence, in order to further reduce the size of devices on integrated circuits, it has become necessary to use insulators that have a lower dielectric constant than the insulators of previous generations of integrated circuits. To this end, semiconductor manufacturers, materials suppliers and research organizations among others have been researching and developing materials for use as premetal dielectric (PMD) layers and intermetal dielectric (IMD) layers in integrated circuits that have a dielectric constant (k) below that of silicon dioxide (generally between about 3.9-4.2) and below that of fluorine-doped silicate glass (FSG, generally between 3.4-3.7). These efforts have resulted in the development of a variety of low dielectric constant films (low k films). As used herein, low k films are those having a dielectric constant less than about 3.0 including films having a dielectric constant below 2.0.

Some approaches to developing such low k films include introducing porosity into known dielectric materials to reduce the material's dielectric constant. Dielectric films when made porous, tend to have lower dielectric constants (the dielectric constant of air is normally 1.0). It is known that aerogels and xerogels have very high porosity, and subsequently very low dielectric constants (e.g., as low as 1.1 or less). Several drawbacks exist to using these approaches in semiconductor fabrication techniques, however. First, the materials are not mechanically robust and therefore have difficulty surviving the integration process employed in chip manufacturing. Also, the porosity is made up of a broad distribution of pore sizes. This causes problems in etching and in achieving a uniform sidewall barrier coating.

Another possible class of porous silica materials is zeolites. Methods are known to prepare thin films of zeolites, but the relatively low porosity of these films prevents them from achieving dielectric constants in the low end of the range expected of low k materials.

Still another class of low k materials includes ordered mesoporous silica materials. One known method of forming such ordered mesoporous oxide films is referred to as the sol gel process, in which high porosity films are produced by hydrolysis and polycondensation of a metal oxide. The sol gel process is a versatile solution process for making ceramic material. In general, the sol gel process involves the transition of a system from a liquid “sol” (mostly colloidal) into a solid “gel” phase. The starting materials used in the preparation of the “sol” are usually inorganic metal salts or metal organic compounds such as metal alkoxides. The precursor solutions are typically deposited on a substrate by spin on methods. In a typical sol gel process, the precursor is subjected to a series of hydrolysis and polymerization reactions to form a colloidal suspension, or a “sol.” Further processing of the “sol” enables one to make ceramic materials in different forms.

In one particular sol gel process for forming a porous low k film, surfactants act as the template for the film's porosity. The porous film is generally formed by the deposition on a substrate of a sol gel precursor followed by selective evaporation of components of the sol gel precursor to form supramolecular assemblies. The assemblies are then formed into ordered porous films by the pyrolysis of the supramolecular templates at temperatures between 300-450° C. The pyrolysis step for this process, however, can require as much as four hours extracting the surfactant and leaving behind a porous silicon oxide film. Such lengths of time are incompatible with the increasing demand for higher processing speeds in modem semiconductor processing.

Accordingly, several sol gel processes have been developed that have reduced formation times by allowing for rapid evaporation of solvent from a preformed silica precursor solution. One such process forms an initial silica sol (stock solution) by refluxing a soluble organosilicate glass (OSG) precursor, e.g., TEOS (tetraethoxysilane), water, a solvent, e.g. ethanol, and an acid catalyst, e.g. hydrochloric acid, at certain prescribed environmental conditions for certain time periods and at particular mole ratios. Once the stock solution is obtained, a coating solution is then prepared by adding to the stock solution a surfactant along with additional TEOS, water, solvent and catalyst.

Surfactants are used as templates for the porous silica. In later steps of the process the surfactants are baked out, leaving behind a porous silicon oxide film. Typical surfactants exhibit an amphiphilic nature, meaning that they can be both hydrophilic and hydrophobic at the same time. Amphiphilic surfactants posses a hydrophilic head group or groups which has a strong affinity for water and a long hydrophobic tail which repels water. The long hydrophobic tail acts as the template which later provides the pores for the porous film. Amphophiles can aggregate into supramolecular arrays which are precisely the desired structure that needs to be formed as the template for the porous film. Templating oxides around these array leads to materials that exhibit precisely defined pore sizes and shapes. The surfactants can be anionic, cationic, or nonionic. The acid catalyst is added to accelerate the condensation reaction of the silica around the supramolecular aggregates.

After the coating solution is prepared, it is filtered and applied onto the surface of the substrate to be coated (typically a silicon wafer) by spin coating. The coated substrate is then pre-baked at a temperature chosen to allow for the preferential removal of the solvent relative to the water. This pre-bake step completes the hydrolysis of the TEOS precursor, continues the gelation process and drives off any remaining solvent from the film. After being pre-baked, the substrate is further baked at a temperature chosen to ensure that the water gets boiled out of the coating solution to form a hard-baked film. At this stage the film is comprised of a hard-baked matrix of silica and surfactant with the surfactant possessing an interconnected structure characteristic of the type and amount of surfactant employed. The interconnected structure is required to allow for the subsequent surfactant extraction phase. The interconnected structure provides continuous pathways for the subsequently burned off surfactant molecules to escape from porous oxide matrix.

Typical silica-based films often have hydrophilic pore walls and aggressively absorb moisture from the surrounding environment. If water, which has a dielectric constant of about 78, is absorbed into the porous film, then the low k dielectric properties of the film can be detrimentally affected. Often these hydrophilic films are annealed at elevated temperatures to remove moisture and bum and extract the surfactant out of the precursor-surfactant matrix. This leaves behind a porous film exhibiting interconnected pores, but is only a temporary solution in a deposition process since the films are still sensitive to moisture contamination following this procedure. Thus, the film may be further stabilized by depositing a capping or passivation layer over the porous dielectric layer.

While the above described sol gel deposition process can be used to deposit low k films, semiconductor manufacturers continuously seek improvements to existing technology. Accordingly, the semiconductor industry is currently spending much time and effort researching improvements to, as well as alternatives to, processes to deposit extremely low dielectric constant films.

### BRIEF SUMMARY OF THE INVENTION

Embodiments of the present invention pertain to improved and/or alternative methods of depositing low k films. Some specific embodiments of the invention pertain a method of and an apparatus for preparing a low k coating solution by mixing various constituents of the solution shortly before their use, aging the mixed coating solution for a predetermined time and then delivering the aged solution to solution applicator, e.g., a dispenser in a spin coating device or an ultrasonic spray nozzle.

One embodiment of the method of the invention includes combining, in a mixing apparatus fluidly coupled to a solution applicator, a soluble organosilicate glass (OSG) precursor, a solvent and a surfactant with water and an acid catalyst to form a coating solution; aging the coating solution in the mixing apparatus to form an aged coating solution; transporting the aged coating solution to the solution applicator; and then applying the aged coating solution to the substrate with the applicator.

Another embodiment of the method of the invention forms a low dielectric constant material over a substrate by providing first, second and third supply tanks containing first, second and third solutions, respectively. The first solution comprises an organosilicate glass (OSG) precursor and a surfactant and is formulated to enable formation of a material having a first dielectric constant. The second solution comprises an organosilicate glass (OSG) precursor and a surfactant and is formulated to enable formation of a material having a second dielectric constant that is lower than the first dielectric constant. And the third solution comprises an acid catalyst diluted in water. The method includes delivering selected amounts of each of the first, second and third solutions to a mixing tank along with solvent to form a coating solution; mixing the coating solution in the mixing tank; aging the coating solution to form an aged coating solution; transporting the aged coating solution to a solution applicator that is fluidly coupled to the mixing tank; and applying the aged coating solution to the substrate with the solution applicator.

Still another embodiment of the method of the invention includes providing first, second, third and fourth supply tanks that contain first, second, third and fourth solutions, respectively. The first solution comprises a soluble OSG precursor, the second solution comprises a solvent, the third solution comprises a surfactant, and the fourth solution comprises an acid catalyst diluted in water. Selected amounts of each of the first, second, third and fourth solutions are delivered to a first mixing tank where they are mixed to form a coating solution. The mixed solution is aged a predetermined time to form an aged coating solution and then transported to a solution applicator that is fluidly coupled to the mixing tank. The mixed and aged solution is then applied to the substrate with the solution applicator.

In accordance with another embodiment, an apparatus for mixing chemicals and delivering said mixed chemicals to a solution applicator in a substrate processing apparatus is disclosed. The mixing apparatus includes first and second chemical supply tanks, a mixing tank, a filter and a valve. The mixing tank is fluidly coupled to receive chemicals from the first and second chemical supply tanks through at least a first inlet. The mixing tank also has a second inlet as well as an outlet to dispense a mixed solution. The filter has an inlet fluidly coupled to the mixing tank outlet to receive the mixed solution from the mixing tank and an outlet to deliver filtered solution to the solution applicator, and the valve is operatively coupled between the filter outlet and the solution applicator to selectively deliver the filtered solution to either the solution applicator or to the second inlet of the mixing tank.

These and other embodiments of the present invention, as well its advantages and features, are described in more detail in conjunction with the description below and attached figures.

### BRIEF DESCRIPTION OF THE DRAWINGS

FIG. 1 is a simplified, block level diagram of a chemical mixing, aging and delivery apparatus according to one embodiment of the present invention;

FIG. 2 is a detailed flow diagram of a chemical mixing, aging and delivery apparatus according to another embodiment of the present invention;

FIG. 3 is a simplified cross-sectional view of one embodiment of a mixing tank shown in FIG. 2; and

FIG. 4 is a flow chart showing the steps used in the formation of a low k film according to one embodiment of the present invention.

### DETAILED DESCRIPTION OF THE INVENTION

As previously mentioned, certain embodiments of the invention pertain to a method for forming surfactant-templated, ordered mesoporous films. While the method of the invention is particularly useful in forming ordered mesoporous silicon oxide films, it can be applied to forming other types of ordered mesoporous ceramic films as well. More specifically, the method of the invention is useful for forming mesoporous ceramic materials including, but not limited to, alumina, aluminum nitride, titania, titanium silicate, titanium carbide, silicon carbide and silicon nitride among others.

According to some embodiments of the invention, the solutions from which such films are formed (hereinafter referred to generically as “coating solutions”) include at least five different components: a soluble OSG precursor, a surfactant, an acid catalyst, water and a solvent. The ratio of these various components can be formulated to provide for a coating solution that cures very rapidly—a generally desirable property in the semiconductor industry as cure times have a direct effect on wafer throughput, which in turn, has a direct effect on cost of operation of a semiconductor fabrication facility.

Generally speaking though, solution reactivity is inversely related to solution shelf life. Thus, rapid cure formulations tend to have a short shelf life, and the more reactive a particular solution formulation is, the shorter its shelf life. The present inventors have found many highly reactive formulations for coating solutions that may otherwise be desirable to use for the formation of ordered mesoporous oxide films have shelf lives that are too short to be reliably used in the semiconductor industry.

Certain embodiments of the present invention solve this problem by mixing the coating solution from its various constituents shortly before the solution is to be used in a mixing apparatus that is fluidly coupled to the apparatus that applies the solution to substrates. Such mixing can be referred to as “point-of-use” mixing as compared to mixing a coating solution in an apparatus that fills solution tanks for storage and/or subsequent delivery to a coating apparatus. These methods also provide for aging the mixed solution at the mixing apparatus for a predetermined time before the solution is used. Typically the coating solution is somewhat unstable immediately after being mixed. Using the solution at this stage could result in undesired variations in film properties between successively deposited films and/or between successively mixed batches of coating solution. Aging the solution a predetermined time, for example, between 30 and 120 minutes, allows the solution to stabilize so that subsequent film formation processes can produce highly uniform films.

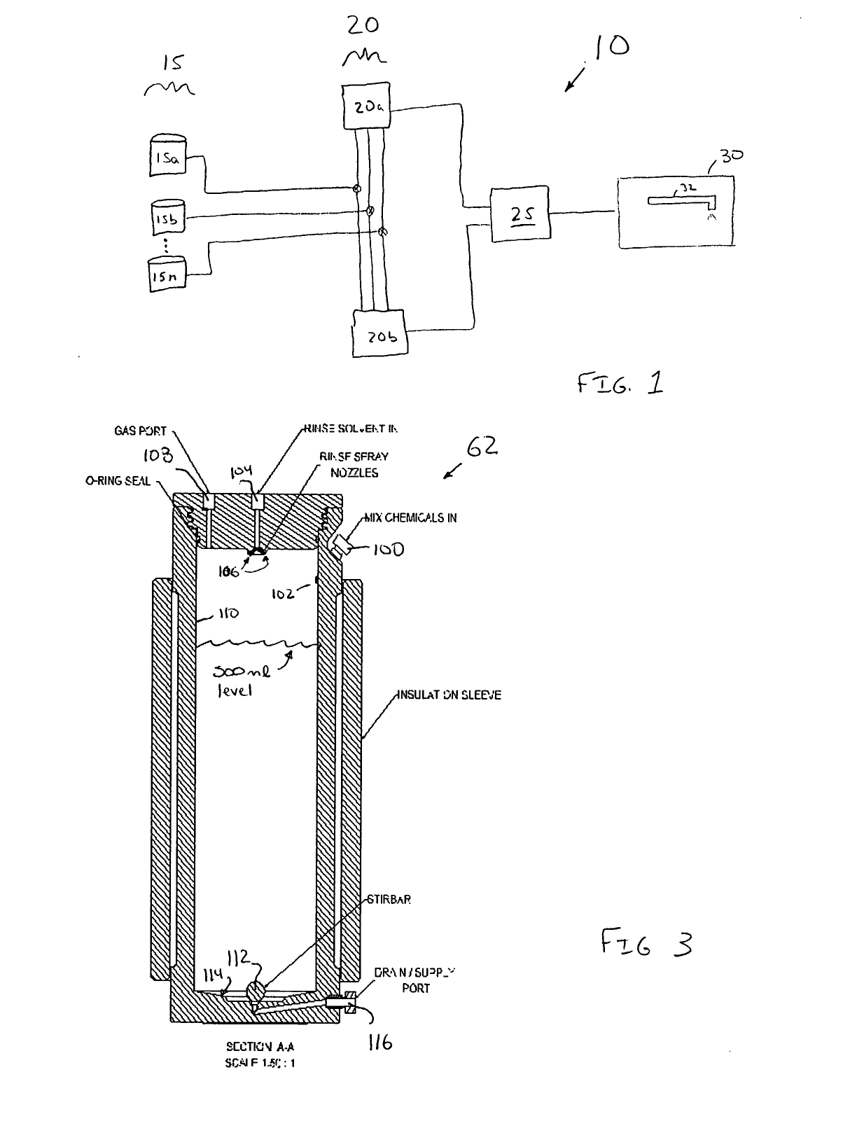

FIG. 1 is a simplified, block level diagram of a chemical mixing, aging and delivery apparatus 10 (sometimes referred to herein as just “mixing apparatus 10”) according to one embodiment of the present invention. As shown in FIG. 1, several of the primary components of apparatus 10 include chemical sources 15, mixing tanks 20 and filter 25. Mixing apparatus 10 also includes various fluid control valves, pipes and measurement sensors (not shown) that are discussed in more detail below. For convenience of illustration, further description of mixing apparatus 10 is with respect to its use in mixing coating solutions for ordered, mesoporous silicon oxide films. In other embodiments, however, apparatus 10 may be used to mix, age and deliver other chemical solutions for the formation of other types of mesoporous ceramic materials. Apparatus 10 can also be used to deliver mixed solutions to other substrate processing systems, such as apparatuses that deposit photoresist films or deliver chemical mechanical polishing (CMP) slurries to a CMP apparatus.

Chemical sources 15 include multiple chemical tanks, tanks 15a . . . 15n, that can store different chemicals. Similarly, mixing tanks 20 include at least two separate mixing tanks: mixing tanks 20a and 20b. This allows for a coating solution to be mixed and prepared and then subsequently aged in one tank (e.g., tank 20a) while the other tank (tank 20b) is used to deliver a previously mixed and aged coating solution to a solution applicator 32 in a substrate processing apparatus 30.

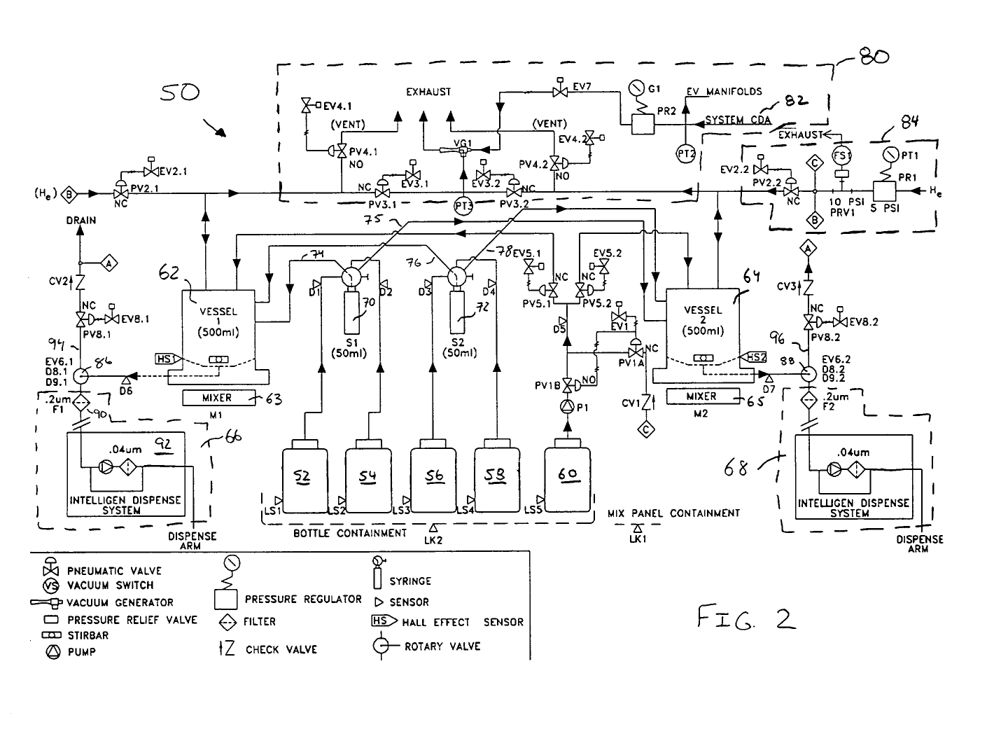

The mixing of a particular coating solution typically results in the production of particles that would be detrimental to the yield of integrated circuits fabricated on a substrate with low k films formed the mixed solutions if such particles were deposited on the substrate. Accordingly, when a coating solution is ready to be applied to a substrate it is first passed through one or more filters 25. In one embodiment, filter 25 is a single filter designed to filter out particles above a predetermined size, e.g., 0.4 microns. An appropriate valve switches the input to filter 25 between mixing tank 20a and mixing tank 20b as appropriate. In other embodiments, such as the one described with respect to FIG. 2, filter 25 includes multiple filters and/or multiple-stage filters.

Chemical sources 15 include at least first and second chemical tanks 15a and 15b that hold different chemicals. In some embodiments chemical sources 15 include three, four, five or even more separate tanks (shown as tanks 15c, 15d and 15n). In a minimum configuration for forming mesoporous silicon oxide coating solutions, two tanks (tanks 15a and 15b) are used such that tank 15a holds all non-aqueous solutions and tank 15b holds all aqueous solutions. Thus, for example, tank 15a may store the soluble OSG precursor, the solvent and the surfactant, while tank 15b may store water and the acid catalyst. In other embodiments additional chemicals, for example, a film surface modifier and/or an ionic salt, are used. In such embodiments, the film surface modifier may be stored in non-aqueous solution tank 15a while the ionic salt is stored in aqueous solution tank 15b.

In another embodiment, four separate tanks are employed: tank 15a holds the soluble OSG precursor, tank 15b holds solvent, tank 15c holds surfactant diluted in solvent and tank 15d holds the acid catalyst diluted in water. This embodiment enables precise control over both film thickness and the dielectric constant of the formed film by allowing independent adjustment of the amount of surfactant and solvent introduced into the mixing solution. The amount of surfactant included in the solution has a direct affect on the film's porosity, which in turn has a direct affect on the film's dielectric constant. More surfactant results in a higher porosity and thus a lower k value. Less surfactant results in lower porosity and a higher k value. Similarly, the amount of solvent added had a direct effect on film thickness. More solvent results in thinner coated films while less solvent results in thicker coated films. If such an embodiment includes a film surface modifier and/or an ionic salt, the film surface modifier may be stored in tank 15a while the ionic salt is stored in tank 15d.

Another four tank embodiment provides control of the k value between a high value and a low value by providing two separate tanks that hold different formulations of the OSG precursor and surfactant. For example, in one four tank embodiment, tank 15a holds a first, higher value low dielectric constant (e.g., k=2.2) formulation of a soluble OSG soluble source, solvent and a surfactant, while tank 15b holds a second, lower value low dielectric constant (e.g., k=1.9) formulation of a soluble OSG soluble source, solvent and a surfactant. Tank 15c holds additional solvent and tank 15d holds the acid catalyst diluted in water. This embodiment enables precise control over film thickness by allowing adjustment of the amount of solvent introduced into the mixing solution. The embodiment also enables control of the dielectric constant between the high and low values (e.g., between 2.2 and 1.9) by adjusting the amount of solution from tank 15a versus tank 15b.

In still other embodiments, three separate tanks 15a, 15b and 15c are employed. In one three-tank embodiment, the contents of tanks 15b and 15c (from the first four-tank embodiment described above) are combined together. This does not allow for thickness and k value to be controlled independent of each other than the control that exists in selecting the composition of tanks 15a-15c. In another three-tank embodiment, tank 15c (from the first four-tank embodiment) is not used and instead, the surfactant is added to tank 15a. This embodiment allows control of film thickness but does not allow much control of the dielectric constant other than by altering the formulation of the tank 15a solution.

In each of the embodiments just described, a separate tank, e.g., tank 15n, can be used to store a separate rinsing solution that can be used to rinse out and clean the various fluid lines, mixing tanks and other components of system 10 as needed. Examples of suitable rinsing solutions include isopropanol alcohol or a solution such as propylene glycol monopropyl ether (PGPE).

Tanks 15a-15n can be made from any suitable, nonreactive material. In the four tank embodiment mentioned above, tanks 15a, 15c, 15d and 15n are made from fluorinated polyethylene (FLPE) while solvent tank 15b is made from high density polyethylene (HDPE). Tanks 15a-15n can also be any appropriate volume.

FIG. 2 is a detailed flow diagram of a mixing apparatus 50 according to another embodiment of the present invention. As shown in FIG. 2, apparatus 50 includes five separate chemical storage tanks 52, 54, 56, 58 and 60; two mixing tanks 62 and 64; two filters 66 and 68; two precision syringes 70 and 72 and numerous fluid pipes (most of which are not labeled) that interconnect the various components of mixing apparatus 50 to transport chemicals and mixed solutions from one component to the next.

In operation, chemicals are drawn from storage tanks 52-58 by precision syringes 70 and 72 into one of the mixing tanks 62 or 64. Syringe 70 draws fluid from tanks 52 and 54 while syringe 72 draws fluid from tanks 56 and 58. Each syringe has an output that is switchable between mixing tank 62 and mixing tank 64. This enables one of the mixing tanks to be used for mixing and/or aging a coating solution while the other tank is used as a supply for dispensing a previously mixed and aged coating solution onto a substrate. In other embodiments, additional or fewer syringes may be used and/or each syringe may draw fluid from fewer or more tanks.

Since each syringe draws fluid out of multiple tanks 52-58, the filling of mixing tanks 62 and 64 requires sequenced steps. For example, in one embodiment where tank 52 holds the soluble OSG precursor and a film surface tension modifier, tank 54 holds solvent, tank 56 holds surfactant diluted in solvent and tank 58 holds the acid catalyst diluted in water and an ionic additive, syringe 70 primes tank 52 to void the tank and the fluid pipe between the syringe and tank 52 of air and then draws chemical from the tank directly into the syringe. The syringe can draw up to 50 ml of chemical from tank 52 before delivering the drawn chemical to mixing tank 62. Depending on the amount of chemical from tank 52 required for the solution, additional chemical can be drawn in a second step.

Once sufficient chemical from tank 52 is delivered to mixing tank 62, syringe 70 draws solvent from tank 54 for delivery to mixing tank 62. The inventors have found that the soluble OSG precursor stored in tank 52 may start to polymerize if exposed to vapors from mixing tank 62 during the mixing process. In this embodiment, solvent from tank 54 is delivered to mixing tank 62 after the appropriate amount of solution from tank 52 is delivered to the mixing tank. Since syringe 70 delivers the chemicals from tanks 52 and 54 to mixing tank 62 through the same line 74, this “washes” residual chemical from tank 52 from the line and prevents polymerization of the chemical in the line 74. Similarly, for mixing tank 64, solvent from tank 54 is used to wash line 75 after the mixing tank is filled with solution from tank 52.

Concurrent with the delivery of chemicals from tanks 52 and 54, syringe 72 draws chemicals from tanks 56 and 58, in sequence, and delivers the drawn chemicals to mixing tank 62. Fluid lines 76 and 78 between syringe 72 and mixing tanks 62 and 64, respectively, do not need to be rinsed with solvent as do lines 74 and 75 since the chemicals in tanks 56 and 58 are not susceptible to polymerization if exposed to vapors from the mixing tank.

Syringes 70 and 72 as well as other flow control valves shown in FIG. 2 are controllable by a computer processor (not shown) as would be understood by a person of skill in the art. Suitable syringes 70 and 72 are available from manufacturers such as Cavro Scientific and Kloehn. In other embodiments, different volume syringes, micropumps or a combination of micropumps and micro syringes can be used. In one embodiment, a combination ceramic micropump (80% volume) and micro syringe (20% volume) is used to provide an optimal balance between speed and accuracy. This could be done, for example, by using a micropump to deliver the larger volume components to the mixing tanks and using a micro syringe to deliver the smaller volume components. In still other embodiments, appropriate solution amounts can be measured volumetrically, for example, with sight tubes and optical sensors and then delivered to the mixing tanks. In still another embodiment, mixing tanks 62 and 64 can include highly sensitive load cells that measure the weight of the coating solution delivered into the tanks and can be used to stop the delivery of additional solutions from tanks 52, 54, etc. upon reaching certain predetermined weight measurements.

Mixing tanks 62 and 64 can be made from any suitable non-reactive, hard material and be any appropriate size. In one embodiment, mixing tanks 62 and 64 are machined from natural (unpigmented) polypropylene and hold between 250 milliliters to 4 liters of solution in order to allow for operation of the fluidly coupled substrate processing system for two hours. Also, in some embodiments, mixing tanks 62 and 64 can include a temperature control jackets, known to those of skill in the art, that dissipate the heat generated during the process of mixing the coating solution.

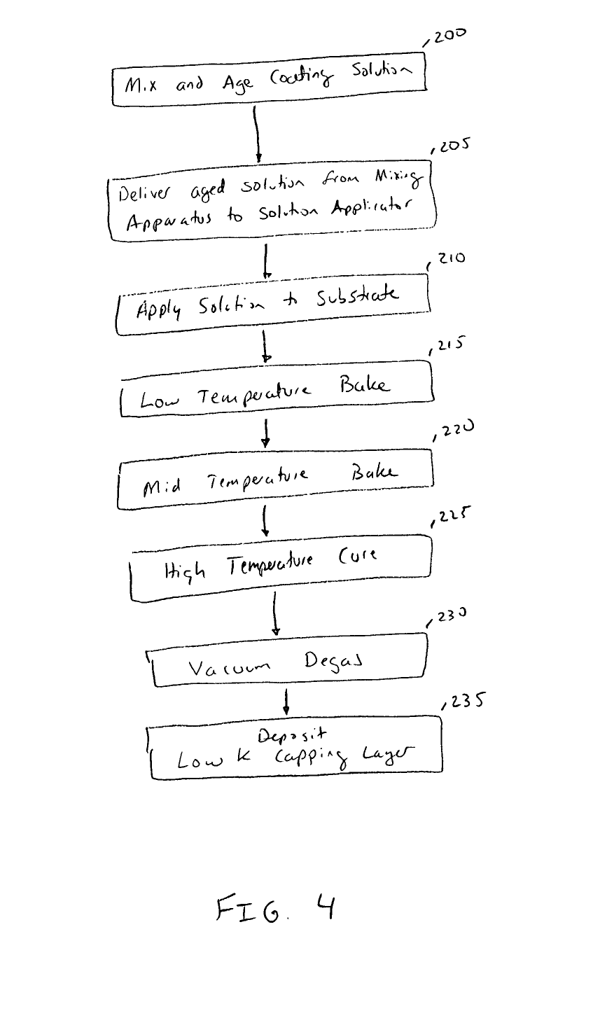

A more detailed view of an individual mixing tank according to one embodiment of the invention that is designed to hold up to 500 ml of mixed solution is shown in FIG. 3, which is a cross-sectional view of mixing tank 62. As previously discussed, chemicals from tanks 52, 54 are delivered to mixing tank 62 through lines 74 and 76. As shown in FIG. 3, line 74 couples to tank 62 at a coupling 100. Chemicals from line 74 are introduced into mixing tank 62 at an inlet 102 that is fluidly coupled to the opening in coupling 100 and positioned above the 500 ml tank level. Similarly, while not shown because of the cross-sectional nature of FIG. 3, line 76 couples to a second coupling and chemicals from line 76 are introduced into tank 62 from a second inlet that is also position above the 500 ml tank level. A third inlet 104 receives rinsing solution from rinsing tank 60. Inlet 104 is positioned above inlets 100 and 102 and is designed to spread the rinsing solution through nozzles 106 along the entire sidewall 110 of mixing tank 62 so that a small amount of rinsing solution can adequately rinse residual solution from the tank sidewall.

Mixing tanks 62 and 64 also include agitators, such as magnetic stirrers 63 and 65, that rotates within the tank. As shown in FIG. 3, in one embodiment, magnetic stirrer 63 includes a mixing stirbar 112 (pointed in a plane perpendicular to the plane of FIG. 3) that sits within a bottom recessed portion 114 of the mixing tank. Stirbar 112 can be made from or coated with a nonreactive, non-particle shedding material.

In operation, after all the appropriate chemicals are delivered to mixing tank 62 to form the coating solution, the solution is mixed for a period of time by blade 112. Next, the mixed solution is allowed to age in the tank an appropriate amount of time before it is ready for use. In one embodiment, the coating solution is mixed in tank 62 for between 1 and 10 minutes and then allowed to age in tank 62 for between 30 and 120 minutes before it is ready for use.

Mixing tank 62 also includes an inlet/outlet 108 that provides for at least three different uses. First, inlet/outlet 108 allows the application of a slight vacuum during the mixing process in order to prevent or at least reduce the amount of microbubbles that are formed in the solution. Venturi vacuum generation system 80 (FIG. 2) generates vacuum pressures from a supply of clean dry air 82 (FIG. 2) as is known to those of skill in the art. Other types of vacuum systems, e.g., a chemically resistant vacuum pump, can be used in other embodiments. After a period of time, vacuum is displaced by helium pressure applied through inlet/outlet 108 from a helium source 84 (FIG. 2). Inlet/outlet 108 also allows any gases present in tank 62 to be vented during the tank filling process. Switching between the above-described three functions is done using the various valves shown in FIG. 2.

After a coating solution is mixed and aged in tank 62, solution can be drained from the tank under vacuum pressure through a drain 116. Drain 116 lies centered in the bottom of recessed portion 114 of tank 62 in order to allow the tank to drain as evenly and fully as possible. The helium pressure is sufficient to transport the drained solution (from tank 62) to a valve 86 where it is then directed to either a waster stream or filter system 66 prior to being delivered to the solution applicator of the substrate processing apparatus. In one embodiment, valve 86 is a rotary valve that has essentially zero dead volume and thus does not trap or introduce unwanted air into the solution.

In the embodiment shown in FIG. 2, the drained solution is passed through a multi-stage filter. A first stage 90 of the filter includes a large particle, (e.g., 0.2 micron) filter that filters crystals and other large particles out of the solution. Next, the solution is passed through a second-stage filter 92. Filter 92 filters smaller diameter particles (e.g., 0.04 microns) and may include separate pre- and post-filter stages. In one embodiment, filter 92 allows for separate control of dispense and filtration rates. One suitable filter, referred to as an Intelligen Dispense System, is manufactured by Mikrolis. Shortly after passing through filter 92, the mixed and aged coating solution is ready to be applied to an appropriate substrate and is thus delivered to an applicator, e.g., a dispense arm in a spin-coating device or an ultra sonic spray nozzle, in an appropriate substrate processing apparatus.

Apparatus 50 includes fluid lines 94 and 96 that allow for the coating solution to be drained to an appropriate fluid collection and treatment facility. Apparatus 50 also includes a number of sensors to monitor fluid levels and detect when fluid replacement is necessary. These sensors include both capacitive sensors LS1 to LS5 and optical liquid level sensors D1 to D7. Suitable optical liquid level sensors are available from manufacturers such as Banner and Keyence, while suitable capacitive sensors are available from SIE-Sensorik and Carlos Galvazzi. Apparatus 50 also includes leak sensors LK1 and LK2 in order to detect leaks that may require immediate attention.

Fluid flow from mixing tank 64, through filter 68 to a substrate processing apparatus mirrors the fluid flow just described. The separate flows can be directed to different solution applicators or the same fluid applicator. If directed to different applicators, the applicators can be part of the same substrate processing tool, e.g., two dispensers that can dispense solution to a single spin-on-dielectric cup, or part of different tools.

In an embodiment not shown in FIG. 2, the outputs of pumps 66 and 68 are switchable between a solution applicator in a substrate processing apparatus and their respective mixing tanks 62 and 64. When coating solution is not being dispensed to the substrate processing apparatus in this embodiment (e.g., when substrates are being transferred from and to the apparatus), the solution is circulated through filter system 66 to better control crystal and particle formation within the solution. In systems that have two separate filter systems 66 and 68, such solution recirculation can be continuously performed for both tanks 62 and 64 thus allowing recirculation during the mixing and aging process as well during appropriate times in the solution delivery sequence. In another embodiment, an appropriate switchable valve exists between the first and second stage filters 90 and 92 that allows the coating solution to be continuously recirculated between tank 62 and filter 90 when solution is net being delivered to the substrate processing apparatus.

As previously mentioned, embodiments of the invention enable a number of different coating solutions that would not otherwise be possible to use for the formation of low k films in integrated circuit applications due to short shelf life issues. These embodiments eliminate the shelf life issue by combining two or more components of the solution immediately prior to use in a point-of-use mixing, aging and delivery system, such as the system described with respect to FIGS. 1-3. Other embodiments of the invention may use other point-of-use mixing systems that are available from various vendors. The embodiments also eliminate the need to add various solution stabilizing chemicals or modifying agents to the coating solution as has been contemplated by some in the industry. Such modification techniques tend to reduce the cross-linking that occurs in a forming film and therefore slows the hardening process. They also, reduce the solutions reactivity, however, and therefore require longer cure steps.

Mixing the low k coating solution at the point-of-use using separate chemical tanks allows semiconductor manufacturers to separately control the amount of surfactant and the amount of solvent added to the coating solution and therefore change the characteristics of the low k films formed from the coating solution with minimal effort. For example, a semiconductor manufacturer can prepare a table of different coating solution formulations that enable the formation of low k films having different properties including different thickness, different k values and different modulus of elasticity among others. The table can be stored in a computer-readable format and made accessible to the computer control system that controls the delivery of the various chemicals to the mixing tanks. Engineers or other tool operators can then select the desired film properties using the computer control system and have the system automatically deliver the appropriate amounts of each chemical to the mixing tank to prepare a coating solution that will form a film having the desired properties.

As previously mentioned, the techniques of the present invention are particularly useful in forming ordered mesoporous silicon oxide films. In some embodiments, the coating solutions from which such films are formed include at least five different components: a soluble OSG precursor, a surfactant, an acid catalyst, water and a solvent. In order to provide the most control and flexibility in the formation of films from such a coating solution, various embodiments of the invention mix the solution from four separate chemical supplies. In one of these embodiments, a first supply contains a first, higher value low dielectric constant formulation of one or more soluble silica and/or OSG precursors, a surfactant and a solvent. A second supply contains a second, higher value low dielectric constant formulation of one or more soluble silica and/or OSG precursors, a surfactant and a solvent. The third supply holds additional solvent and the fourth supply holds the acid catalyst diluted in water. Optionally, a film surface modifier that increases the spreading of the film can be added to any or all the first, second or third supplies. An example of such a surface modifier is polydimethyldisoloxane, which the inventors have found to be useful in improving the uniformity of low k film formation when a coating solution is prepared to deposit a film of about 4000Å or thicker. Also, an ionic additive can be added to the supply of acid and water. Such an ionic additive is particularly useful when employing highly pure surfactants as described in copending U.S. application Ser. No. 09/823,932 entitled “Ionic Additives for Extreme Low Dielectric Constant Chemical Formulations,” and having Robert P. Mandel, Alex Demos, Timothy Weidman, Michael P. Nault, Nikolaos Bekiaris, Scott J. Weigel, Lee A. Senecal, James E. Mac Dougall, Hareesh Thridanam listed as inventors. The 09/823,932 application is hereby incorporated by reference for all purposes.

When forming a mesoporous oxide film, suitable organosilicate glass precursors include tetraalkoxysilanes such as tetraethylorthosilicate (TEOS) alone or in combination with an alkyl substituted silica precursor such as methyltrioxysilane (MTES) or another methyltryalkoxysilane. The addition of an alkyl substituted silica precursor (for example 30-70% by volume of the total silicon precursor present) to a tetraalkoxysilane has been found to produce films exhibiting good resistance to moisture absorption without requiring the films to be subjected to a dehydroxylating process, e.g., by exposure to hexamethyldisilizane (HMDS) vapors, which react with hydroxyl groups and render the film hydrophobic.

Suitable solvents include ethanol, isopropanol, propylene glycol monopropyl ether (PGPE) , n-propanol, n-butanol, t-butanol, ethylene glycol and combinations thereof, and suitable acid catalysts include organic acids such as acetic acid, oxalic acid, formic acid, glycolic acid and nitric acid. Suitable surfactants include non-ionic surfactants such as Triton™ 100, Triton™ 114, Triton™ 45, polyethylene oxides-polypropylene oxide triblock copolymers, octaethylene glycol monodecyl ether, octaethylene glycol monohexadecyl ether, as well as related compounds and combinations thereof Such surfactants are available from Sigma-Aldrich, Co.

FIG. 4 shows a simplified flow chart showing the steps involved with preparing a mesoporous silicon oxide film according to one embodiment of the invention. As shown in FIG. 4, after preparing, mixing and aging the coating solution according to any of the embodiments disclosed herein (step 200), the solution is transported to the fluidly coupled solution applicator (step 205) and applied to a wafer using any suitable technique including spin coating and/or spraying methods (step 210). The application step generally takes less than 2 minutes. The coated wafer is transferred from the substrate coating tool to one or more other stations where it is subject to a series of heating steps. First the wafer is subject to a brief, 1-2 minute, first bake step (step 215) to allow for preferential removal of the solvent relative to water. This first bake step occurs at a relatively low temperature, e.g., 90° C., that are below the boiling point of water. Then a second, 1-2 minute, higher temperature, e.g., 180° C., bake step is performed to boil water out of the coating solution and form a hard-baked film (step 220).

The surfactant is then stripped out and the film is cured in a relatively short high temperature cure step (step 225) at atmospheric pressure. Because the method of the present invention allows for the use of rapid-cure coating solutions in application step 205, cure step 225 is less than 5 minutes and can be 1-3 minute range in some embodiments. In one embodiment, cure step 225 occurs in an oxygen and nitrogen environment.

After the film is cured, it is subject to a degas step (step 230) under vacuum conditions, e.g., in the millitorr range in order to further ensure that all the surfactant is driven out. Finally, it is capped with an appropriate low dielectric constant capping material (step 235) as described in U.S. application Ser. No. 09/692,527, entitled “Capping Layer for Extreme Low Dielectric Constant Films, having Timothy Weidman, Michael P Nault, Josephine Chang. The 09/692,527 application is hereby incorporated by reference for all purposes.

low k coating solutions formed according to the techniques described above can have dielectric constants adjustable from between at least 2.2 and 1.9 and one-application thickness adjustable between 1000 Å and 1 micron (10,000 Å). In most commonly envisioned embodiments, the thickness is controllable between 1000 Å to 4000 Å by controlling the amount of solvent added to the coating solution.

### EXAMPLES

Methods of the invention are illustrated below in more detail with reference to the specific examples that demonstrate how the above and other variables may be varied. It should be understood that the following examples are just that, examples, and they should not be deemed to limit or otherwise restrict the scope of the invention in any way. By appropriately partitioning and then combining chemical ingredients, important deposited film properties can be designed and controlled, including film thickness, dielectric constant, modulus, humidity sensitivity, film stress, etc.

In examples 1-4, four different chemical solutions were prepared and stored in tanks 52, 54, 56 and 58 as shown below in Table 1:

TABLE 1

| Tank | Ingredient | Amount (by Tank) | |
|---|---|---|---|
| tank 52 | Tetraethylorthosilicate | 49.98 | weight % or |
| (part A) | (tetraethoxysilane; TEOS): | 48.97 | volume % |
| | Methyltriethoxysilane (MTES): | 49.98 | weight % or |
| | | 51.00 | volume % |
| | BYK 307 (polydimethyl- | 0.0303 | weight % |
| | disiloxane film surface | | |
| | modifier): | | |
| tank 54 | Propylene glycol monopropyl | 100.00% | |
| (part B) | ether (PGPE): | | |
| tank 56 | Propylene glycol monopropyl | 79.54 | weight % or |
| (part C) | ether (PGPE): | 79.37 | volume % |
| | Triton X-114 (polyoxyethylene | 20.46 | weight % or |
| | {8} isooctylphenyl ether): | 20.63 | volume % |
| tank 58 | Aqueous nitric acid, 0.100 N: | 96.00 | weight % or |
| (part D) | | 96.00 | volume % |
| | Aqueous tetramethylammonium | 4.00 | weight % or |
| | hydroxide, 2.40 weight % | 4.00 | volume % |
| | (0.26 N), | | |

Four different mesoporous oxides were then formed as listed below and specific properties of the formed films were measured. In these examples, dielectric constants were determined using a Hg (mercury) contact probe measurement tool, and elastic modulus was measured by nanoindentation using a “Nanoindenter” manufactured by MTS Instruments. Film thickness was measured, after the calcination step, by either spectroscopic elipsometry (as verified by conventional profilometry and low voltage SEM measurements) or using an “n&K” tool using reflectometry and a thin film interference model.

### Example 1

Part A 36.03 vol. %, Part B 8.00 vol. %, Part C 37.70 vol. % and Part D 18.27 vol. %. The resultant chemical formulation was allowed to age and cool in the mixing tank for one hour, filtered through a 0.1 μm filter, and then applied onto a spinning silicon wafer which was then rapidly accelerated to about 2000 rpm (which influences both film thickness and film thickness uniformity) and allowed to partially dry in the spin casting chamber. The resultant film coating the silicon wafer was dried at 90 to 180° C. in air, and then calcined at about 400° C. for about 3-5 minutes in an environment of about 3% oxygen: 97% nitrogen. The resultant film was about 9100 Å thick, exhibited a dielectric constant of about 2.2, a modulus of about 2.7 GPa, low sensitivity to environmental humidity, and low film stress.

### Example 2

Part A 25.41 vol. %, Part B 35.11 vol. %, Part C 26.59 vol. %, Part D 12.89 vol. %. The resultant chemical formulation was allowed to age and cool in the mixing tank for one hour, filtered through a 0.1 μm filter, and then applied onto a spinning silicon wafer which was then rapidly accelerated to about 2000 rpm (which influences both film thickness and film thickness uniformity) and allowed to partially dry in the spin casting chamber. The resultant film coating the silicon wafer was dried at 90 to 180° C. in air, and then calcined at about 400° C. for 3-5 minutes in an environment of about 3% oxygen: 97% nitrogen. The resultant film was about 4200 Å thick, exhibited a dielectric constant of about 2.2, a modulus of about 2.8 GPa, low sensitivity to environmental humidity, and low film stress.

### Example 3

Part A 30.77 vol. %, Part B 0 vol. %, Part C 53.62 vol. %, Part D 15.61 vol. %. The resultant chemical formulation was allowed to age and cool for at least one hour, filtered through a 0.1 μm filter, and then applied onto a spinning silicon wafer which was then rapidly accelerated to about 2000 rpm (which influences both film thickness and film thickness uniformity) and allowed to partially dry in the spin casting chamber. The resultant film coating the silicon wafer was dried at 90 to 180° C. in air, and then calcined at about 400° C. for 3-5 minutes in an environment of about 3% oxygen: 97% nitrogen. The resultant film was about 9500 Å thick, exhibited a dielectric constant of about 1.9, a modulus of about 1.4 GPa, low sensitivity to environmental humidity, and low film stress.

### Example 4

Part A 19.03 vol. %, Part B 38.16 vol. %, Part C 33.16 vol. %, Part D 9.65 vol. %. The resultant chemical formulation was allowed to age and cool for at least one hour, filtered through a 0.1 μm filter, and then applied onto a spinning silicon wafer which was then rapidly accelerated to about 2000 rpm (which influences both film thickness and film thickness uniformity) and allowed to partially dry in the spin casting chamber. The resultant film coating the silicon wafer was dried at 90 to 180° C. in air, and then calcined at about 400° C. for 3-5 minutes in an environment of about 3% oxygen: 97% nitrogen. The resultant film was about 4000 Å thick, exhibited a dielectric constant of about 1.9, a modulus of about 1.5 GPa, low sensitivity to environmental humidity, and low film stress.

In example 5, three different chemical solutions were prepared and stored in tanks 52, 54 and 56 as shown below in Table 2 and used to form a final coating solution having a weight basis of each component as shown in the Table.

TABLE 2

| | | Weight Basis | |
|---|---|---|---|
| Tank | Ingredient | (coating solution) | |
| tank 52 | Tetraethylorthosilicate | 22.5 | grams |
| (part A) | (tetraethoxysilane; TEOS): | | |
| | Methyltriethoxysilane (MTES): | 22.5 | grams |
| | Propyleneglycol propylether (PGPE) | 125 | grams |
| | Ethoxylated octylphenol | 9.67 | grams |
| | (Triton X-114) | | |
| tank 56 | Nitric Acid-0.086N (0.086N HNO₃) | 24.964 | grams |
| (part B) | Tetramethylammonium hydroxide- | 0.0359 | grams |
| | 0.262N (2.4% TMAH in water) | | |
| tank 54 | Propyleneglycol propylether (PGPE) | 14 | grams |
| (part C) | | | |

A mesoporous oxide film was then formed as described above with respect to Examples 1-4 and the film's dielectric constant and thickness was measured. The films exhibited a dielectric constant of 2.2 and a thickness of 3600 Å.

The examples above are given to help illustrate the principles of this invention, and are not intended to limit the scope of this invention in any way. A large variety of variants are apparent, which are encompassed within the scope of this invention. While the invention has been described in detail and with reference to specific examples thereof, it will be apparent to one skilled in the art that various changes and modifications can be made therein without departing from the spirit and scope thereof. These equivalents and alternatives are intended to be included within the scope of the present invention.

What is claimed is:

1. A method for forming a low k dielectric constant material over a substrate, said method comprising:
combining, in a mixing apparatus fluidly coupled to a solution applicator, an organosilicate glass (OSG) precursor, a solvent and a surfactant with water and an acid catalyst to form a coating solution;
aging the coating solution in the mixing apparatus to form an aged coating solution;
transporting said aged coating solution to said solution applicator; and
applying said aged coating solution to said substrate with said applicator.

2. The method of claim 1 wherein said combining step includes mixing at least first and second solutions, wherein said first solution is stored in a first supply tank and comprises said OSG precursor, said solvent and said surfactant and said second solution is stored in a second supply tank comprises said water and said acid catalyst; and.

3. The method of claim 1 wherein said combining step includes mixing at least first, second and third solutions, wherein said first solution is stored in a first supply tank and comprises said OSG precursor and said surfactant, said second solution is stored in a second supply tank and comprises said solvent and said third solution is stored in a third supply tank and comprises said water and said acid catalyst.

4. The method of claim 3 wherein said first solution further comprises solvent.

5. The method of claim 1 wherein said combining step includes mixing at least first, second and third solutions, wherein said first solution is stored in a first supply tank and comprises said OSG precursor, said second solution is stored in a second supply tank and comprises said solvent and said surfactant and said third solution is stored in a third supply tank and comprises said water and said acid catalyst.

6. The method of claim 1 wherein said combining step includes mixing at least first, second, third and fourth solutions, wherein said first solution is stored in a first supply tank and comprises said OSG precursor, said second solution is stored in a second supply tank and comprises said solvent, said third solution is stored in a third supply tank and comprises said surfactant, and said fourth solution is stored in a fourth supply tank and comprises said water and said acid catalyst.

7. The method of claim 1 wherein:
said combining step includes mixing at least first, second, third and fourth solutions, wherein said first solution is stored in a first supply tank and comprises a first portion of said OSG precursor, solvent and a first portion of said surfactant, said second solution is stored in a second supply tank and comprises a second portion of said OSG precursor, solvent and a second portion of said surfactant, said third solution is stored in a third supply tank and comprises said solvent, and said fourth solution is stored in a fourth supply tank and comprises said water and said acid catalyst, and
wherein said first solution is formulated to enable formation of a material having a first dielectric constant and said second solution is formulated to enable formation of a material having a second dielectric constant that is lower than said first dielectric constant.

8. The method of claim 7 further comprising, after said applying step, processing said substrate to form said extremely low dielectric constant material over said substrate and wherein said material has a dielectric constant between said first and second dielectric constants.

9. A method for forming a low k dielectric constant material over a substrate, said method comprising:
dispensing an organosilicate glass (OSG) precursor, water, a solvent, a surfactant and a catalyst into a mixing tank to form a coating solution;
mixing said coating solution in said mixing tank;
aging said coating solution a predetermined time to form an aged coating solution; and
transporting said aged coating solution to a solution applicator that is fluidly coupled to said mixing tank.

10. The method of claim 9 wherein said solution applicator is an ultrasonic spray nozzle.

11. The method of claim 9 wherein said solution applicator is a dispenser in a spin coating device.

12. The method of claim 9 wherein said aged solution is transported to said solution applicator using gas pressure.

13. The method of claim 9 wherein said solution is aged in said mixing tank.

14. The method of claim 9 wherein said OSG precursor oxide comprises tetraethylorthosilicate (TEOS) and methyltriethoxysilane (MTES).

15. The method of claim 9 wherein a surface tension modifier is also dispensed into said mixing tank to form said coating solution.

16. The method of claim 9 wherein said aged coating solution is filtered to remove particles having a diameter larger than a predetermined size prior to being transported to said solution applicator.

17. A method for forming a low k dielectric constant material over a substrate, said method comprising:
providing first, second and third supply tanks containing first, second and third solutions, respectively, wherein said first solution comprises an organosilicate glass (OSG) precursor and a surfactant, said second solution comprises solvent, and said third solution comprises an acid catalyst diluted in water;
delivering selected amounts of each of said first, second and third solutions to a mixing tank to form a coating solution;
mixing said coating solution in said mixing tank;
aging said coating solution a predetermined time to form an aged coating solution;
transporting said aged coating solution to a solution applicator that is fluidly coupled to said mixing tank; and
applying said aged coating solution to said substrate with said solution applicator.

18. The method of claim 17 wherein said aging step is carried out in said mixing tank and wherein said method further comprises:
delivering selected amounts of each of said first, second and third solutions to a second mixing tank to form a second coating solution;
mixing said second coating solution in said second mixing tank; and
aging said second coating solution in said second mixing tank a predetermined time to form a second aged coating solution;
wherein said second aged coating solution is available to be delivered to a solution applicator that is fluidly coupled to said second mixing tank for application onto additional substrates.

19. The method of claim 17 further comprising providing a fourth supply tank comprising a fourth solution comprising an organosilicate glass (OSG) precursor and a surfactant, wherein
said delivering step further comprises delivering a selected amount of said fourth solution to said mixing tank along with said selected amounts of said first, second and third solutions, and
said first solution is formulated to enable formation of a material having a first dielectric constant and said fourth solution is formulated to enable formation of a material having a second dielectric constant that is lower than said first dielectric constant.

20. The method of claim 19 further comprising, after said applying step, processing said substrate to form said extremely low dielectric constant material over said substrate, wherein said formed material has a dielectric constant between said first and second dielectric constants.

21. The method of claim 19 wherein said first and fourth solutions each further comprise solvent.

22. A mixing apparatus for mixing chemicals and delivering said mixed chemicals to a solution applicator in a substrate processing apparatus, said mixing apparatus comprising:
first and second chemical supply tanks;
a mixing tank fluidly coupled to receive chemicals from said first and second chemical supply tanks through at least a first inlet, said mixing tank having a second inlet and having an outlet to dispense a mixed solution;
a filter having an inlet fluidly coupled to said mixing tank outlet to receive said mixed solution from said mixing tank and an outlet to deliver filtered solution to said solution applicator; and
a valve, operatively coupled between said filter outlet and said solution applicator to selectively deliver said filtered solution to either said solution applicator or to said second inlet of said mixing tank.

23. The apparatus of claim 22 wherein said mixing tank comprises a third inlet and is fluidly coupled to receive chemicals from said first chemical supply tank at said first inlet and to receive chemicals from said second chemical supply tank at said third inlet.

24. The apparatus of claim 23 further comprising third and fourth chemical supply tanks, wherein said mixing tank is fluidly coupled to receive chemicals from said first and third chemical supply tanks at said first inlet and to receive chemicals from said second and fourth chemical supply tanks at said third inlet.

25. The apparatus of claim 24 further comprising a first syringe that is operatively coupled to deliver chemicals from said first and third chemical supply tanks to said first mixing tank inlet and a second syringe that is operatively coupled to deliver chemicals from said second and fourth chemical supply tanks to said second mixing tank inlet.

26. A mixing apparatus for mixing chemicals and delivering said mixed chemicals to a solution applicator in a substrate processing apparatus, said mixing apparatus comprising:
a first chemical supply tanks comprising an organo silicate glass precursor, solvent and a surfactant;
a second chemical supply tanks comprising solvent;
a third chemical supply tank comprising an acid catalyst diluted in water;
a mixing tank fluidly coupled to receive chemicals from said first, second and third chemical supply tanks, said mixing tank having an outlet to dispense a mixed solution;
a filter having an inlet fluidly coupled to said mixing tank outlet to receive said mixed solution from said mixing tank and an outlet to deliver filtered solution to said solution applicator.

27. The apparatus of claim 26 further comprising a fourth chemical supply tanks comprising an OSG precursor, solvent and a surfactant;
wherein said mixing tank is also fluidly coupled to receive chemicals from said fourth chemical supply tank.

28. The apparatus of claim 27 wherein at least one of said chemical supply tanks further comprises a surface tension modifier.

29. A method for forming a low dielectric constant material over a substrate, said method comprising:
providing first, second and third supply tanks containing first, second and third solutions, respectively, wherein said first solution comprises an organosilicate glass (OSG) precursor and a surfactant and is formulated to enable formation of a material having a first dielectric constant, said second solution comprises an organosilicate glass (OSG) precursor and a surfactant and is formulated to enable formation of a material having a second dielectric constant that is lower than said first dielectric constant, and said third solution comprises an acid catalyst diluted in water;
delivering selected amounts of each of said first, second and third solutions to a mixing tank along with solvent to form a coating solution;
mixing said coating solution in said mixing tank;
aging said coating solution to form an aged coating solution;
transporting said aged coating solution to a solution applicator that is fluidly coupled to said mixing tank; and
applying said aged coating solution to said substrate with said solution applicator.

30. The method of claim 29 wherein at least some of said solvent is delivered to said mixing tank to form said coating solution from a fourth solution.

31. The method of claim 29 wherein said first and second solutions each further comprise said solvent that is delivered to said mixing tank in said delivering step.

32. The method of claim 31 wherein additional solvent is delivered to said mixing tank from a separate supply of solvent.
